(19) United States
(12) Patent Application Publication
(10) Pub. No.: US 2003/0062196 A1
(43) Pub. Date: Apr. 3, 2003

(54) Anchor point for RF circuit boards and related methods

(76) Inventors: Tina Barcley, Mendon, NY (US); Steven G. McNeal, Lake Orion, MI (US); Elias D. Lebbos, Troy, MI (US); Keith B. Carle, Howell, MI (US)

Correspondence Address: Edwin W. Bacon Jr., DaimlerChrysler Intellectual Capital Corporation, CIMS 483-02-19, 800 Chrysler Drive, Auburn Hills, MI, 48326-2757, US

(21) Appl. No.: 09/970,170

(22) Filed: Oct. 3, 2001

(51) Int. Cl. H05K 1/16

(52) U.S. Cl. 174/260

(57) ABSTRACT

A circuit board includes a first layer of an electrically non-conducting material for carrying circuit components, and a second layer of an electrically conductive material for providing a common ground. At least one spot of a relatively more solderable material than the material of the second layer is in electrical contact with the second layer and is aligned with an opening through the first layer so that electrical connection can be made between the components on the first layer and the second layer by soldering to the spot. These anchor points provide a reliable way to connect circuit components to a common ground, from the top of the circuit board, without having to use backside screws and without having to penetrate the second layer.

### FIELD OF THE INVENTION

The present invention relates generally to connections for components on a circuit board and, more particularly, to connections for circuit board components to an RF ground.

### BACKGROUND OF THE INVENTION

Computers employing radio-frequency (RF) control are increasingly utilized in motor vehicle control systems. Automotive systems commonly include multiple RF circuit boards for a variety of functions that can be interrelated. Such circuits, however, typically must perform under less than optimal conditions for RF signal generation and transmission. For example, when multiple circuit boards are interconnected, the potential is increased for electromagnetic interference that can cause vehicle systems to malfunction. One approach to interconnecting multiple circuit boards for use in motor vehicles is described in commonly assigned U.S. Pat. No. 5,917,149 to Barcley et al. Additionally, automotive system circuit boards are frequently installed in vehicle locations where heat and moisture could adversely affect circuit performance. Automotive RF circuits typically operate over narrow voltage ranges, e.g. over about 5 volts. Where a neutral ground is designated at midrange, for example, at 2.5 volts above the low end of a 5-volt range, errors can result when a signal varies even slightly from its nominal voltage.

The foregoing factors make it desirable to produce tight RF signals, that is, signals that vary from their nominal voltages as little as possible. Thus, for example, where one or more circuits generate multiple RF signals, it is desirable to ground the signals to the same ground plane in order to minimize cross-talk. It also is desirable to protect automotive system circuit boards from excess heat and moisture that could degrade signal quality and accelerate component wear.

Ground plates are commonly made of aluminum. Because of the difficulty of soldering to aluminum, in order to make electrical connections between the circuit components and the ground plate mechanical fasteners, such as screws, rivets, and grommets that extend through the ground plate are used. This presents two problems: First, the holes through the plates can expose the circuit components to moisture and other contaminants. Second, these connections are difficult and expensive to make.

### SUMMARY OF THE INVENTION

The present invention, according to one aspect, is directed to a circuit board that includes a first layer of an electrically non-conducting material for carrying circuit components, and a second layer of an electrically conductive material for providing a common ground. The circuit board also includes at least one spot of a relatively more solderable material than the material of the second layer. The spot is in electrical contact with the second layer and is aligned with an opening through the first layer so that electrical connection can be made between the components on the first layer and the second layer by soldering to the spot. Where the second layer serves as a ground plane, the above described anchor points provide a direct and reliable way to connect circuit components to a common ground, from the top of the circuit board, without having to use backside screws and without having to penetrate the second layer. The resulting circuits thus are less susceptible to water entry and to signal cross-talk. Moreover, they are easier and less expensive to make.

According to another aspect, the present invention is directed to a method of assembling a circuit board. The method includes pressing, e.g. coining, into a conductive substrate at least one spot of a conductive material relatively more solderable than the substrate, and forming at least one opening through a circuit board component layer such that the opening exposes a corresponding spot when the component layer is overlaid upon the substrate. A circuit component mounted on the component layer then is soldered to the exposed spot. The foregoing method provides a reliable way to make electrical connections between the circuit components and a common ground, and allows the conductive spot to be affixed to the substrate without using adhesive.

### BRIEF DESCRIPTION OF THE DRAWINGS

FIG. 1 is a perspective view of a circuit board according to the present invention.

FIG. 2 is a cross-sectional view of an anchor point taken along line 2-2 of FIG. 1.

FIG. 3 is a cross-sectional view of a second embodiment of an anchor point.

FIG. 4 is a cross-sectional view of a third embodiment of an anchor point.

FIG. 5 is a cross-sectional view of a fourth embodiment of an anchor point.

### DETAILED DESCRIPTION OF THE PREFERRED EMBODIMENTS

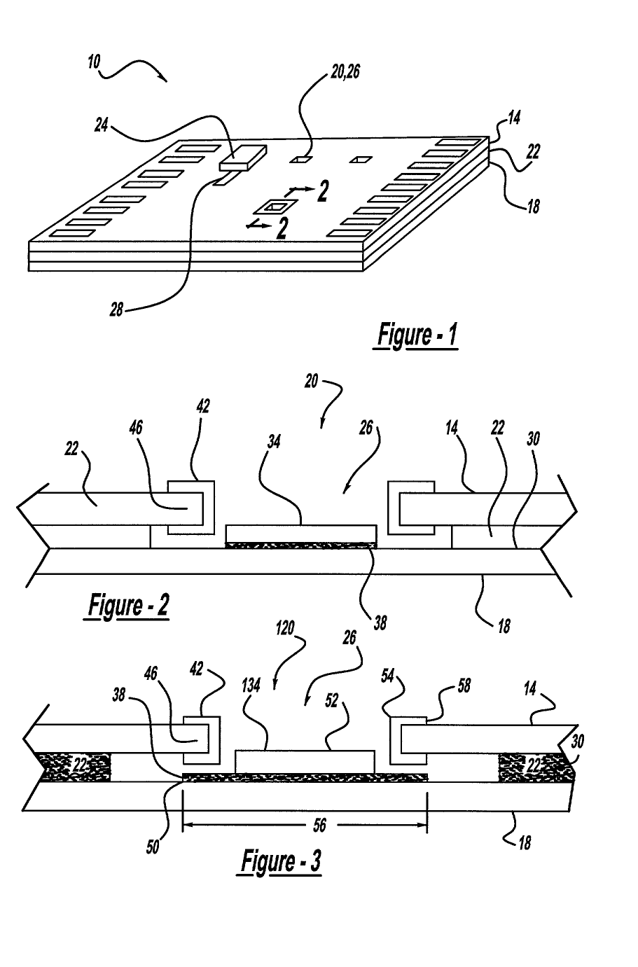

A circuit board in accordance with the invention is generally indicated by reference number 10 in FIG. 1. A component layer 14 is fabricated of an electrically non-conducting material and is configured for placement of circuit components thereon. The component layer 14 is constructed of conventional materials. A substrate 18 is bonded to the component layer 14 with an electrically non-conducting adhesive 22 fabricated, for example, of silicone. The substrate 18 is fabricated of aluminum, although other electrically conductive materials can be used. As further described below, the substrate 18 can serve as a ground plane, rigidizer and/or heat sink for the circuit board 10.

At least one RF anchor point 20 is provided on the circuit board 10 for making electrical connections, as further described below, between the substrate 18 and circuit components mounted on the component layer 14. For example, a component 24 having a lead wire 28 is mounted on the component layer 14. The lead wire 28 is electrically connected to the substrate 18 at an anchor point 20. At each anchor point 20, a hole or opening 26 extends through the component layer 14 to the substrate 18. The openings 26 in the component layer are aligned with spots (not shown in FIG. 1) on the substrate 18.

FIG. 2 is a cross-sectional view of a first preferred embodiment of an anchor point 20 taken along line 2-2 of FIG. 1. Bonded to an upper surface 30 of the substrate 18 is a spot 34 of an electrically conductive material, for example, copper, that is relatively more solderable than the material of the substrate 18. The spot 34 is bonded to the substrate 18 with an electrically conductive adhesive 38 and thus is in electrical contact with the substrate 18. A plated annular rim 42 caps the edge 46 of the component layer 14 and also is fabricated of copper. An electrical connection can be made between a component on the component layer 14 and the substrate 18 by soldering to the spot 34. More specifically and referring to FIGS. 1 and 2, during circuit board assembly, a soldering stencil (not shown) that aligns with the openings 26 through the component layer 14 is placed over the component layer 14, and soldering is performed through the stencil. Solder paste flows into the opening 26, over the spot 34 and into contact with the annular rim 42 to form a solder joint between the component lead wire 28 and the substrate 18.

A second preferred embodiment of an anchor point 120 is shown in FIG. 3. Parts corresponding to those shown in FIG. 2 are indicated by corresponding reference numerals. Two copper foil layers 50 and 52 form an electrically conductive spot 134. The foil layer 50 is bonded to the aluminum substrate 18 with conductive adhesive 38. The foil layer 50 extends at least partly under an inner edge 54 of the annular rim 42. As shown in FIG. 3, the foil layer 50 and an outer edge 58 of the annular rim 42 have approximately the same diameter 56, for example, about 0.25 inches. The foil layer 52 is slightly smaller in diameter than the through-hole 26 and is, for example, about 0.15 inches in diameter.

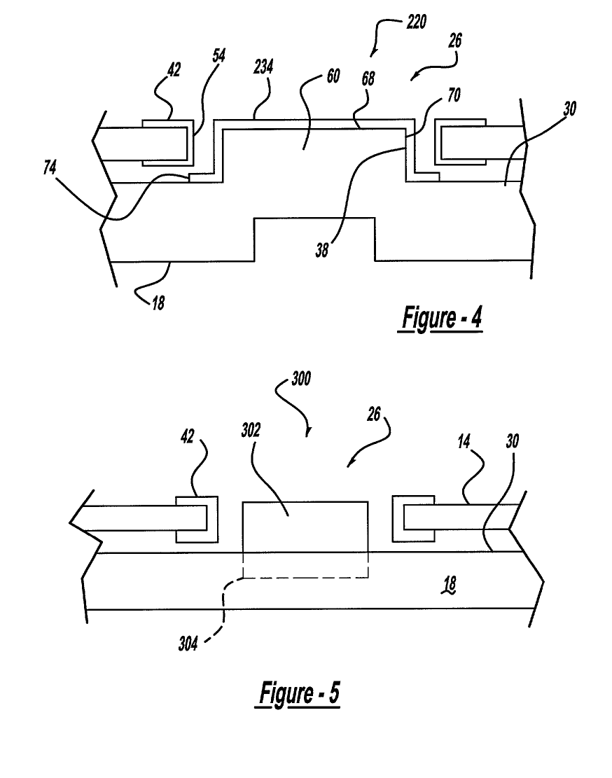

A third preferred embodiment of an anchor point 220 is shown in FIG. 4. Parts corresponding to those shown in FIG. 3 are indicated by corresponding reference numerals. The aluminum substrate 18 is mechanically disrupted, e.g. embossed, to provide a raised land 60 projecting partly into the opening 26. A spot in the form of a copper foil layer 234 is bonded onto the land 60 with conductive adhesive 38. The foil 234 extends over the top 68 and sides 70 of the land 60 and along the upper surface 30 of the substrate 18. The outer edge 74 of the foil 234 aligns approximately with the inner edge 54 of the annular rim 42. Although the shape of the land 60 as shown in FIG. 4 is cylindrical, the substrate 18 can be embossed to form other shapes. The land 60 can have, for example, sloped sides, a curved top and/or rounded edges. The raised land 60 provides mechanical strengthening and also aids in locating the component layer 14 relative to the substrate 18 during circuit board assembly.

A fourth preferred embodiment of an anchor point 300 is shown in FIG. 5. Parts corresponding to those shown in FIG. 2 are again indicated by corresponding reference numerals. A plug 302 of pre-tinned copper is coined into a partial-shear opening 304, for example, a half-shear opening, in the upper surface 30 of the substrate 18.

When installed in a circuit board, the above described anchor points provide a direct and reliable way to connect circuit components to a common ground, from the top of the circuit board, without having to use backside screws and without having to penetrate the substrate. The resulting circuits thus are less susceptible to water entry and to signal cross-talk.

While the invention has been described in the specification and illustrated in the drawings with reference to a preferred embodiment, it will be understood by those skilled in the art that various changes may be made and equivalents may be substituted for elements thereof without departing from the scope of the invention as defined in the claims. In addition, many modifications may be made to adapt a particular situation or material to the teachings of the invention without departing from the essential scope thereof. Therefore, it is intended that the invention not be limited to the particular embodiment illustrated by the drawings and described in the specification as the best mode presently contemplated for carrying out this invention, but that the invention will include any embodiments falling within the description of the appended claims.

What is claimed is:

1. A circuit board comprising:
a first layer of an electrically non-conducting material for carrying circuit components;
a second layer of an electrically conductive material for providing a common ground; and
at least one spot of a relatively more solderable material than the second layer in electrical contact with the second layer and aligned with at least one opening through the first layer such that electrical connection is made between the components on the first layer and the second layer by soldering to the at least one spot.

2. The circuit board according to claim 1, wherein the second layer further comprises at least one raised land projecting at least partly into a corresponding opening through the first layer, and wherein the at least one spot of relatively more solderable material is mounted on the raised land.

3. The circuit board according to claim 2, wherein the raised land is formed by mechanically disrupting the second layer.

4. The circuit board according to claim 2, wherein the at least one spot of relatively more solderable material is mounted on the second layer with an electrically conductive adhesive.

5. The circuit board according to claim 5, wherein the at least one spot comprises:
a first layer of the relatively more solderable material mounted on the second layer of the circuit board and extending at least partly under an edge of a corresponding opening in the first layer of the circuit board; and
a second layer of the relatively more solderable material mounted on the first layer of the relatively more solderable material and projecting at least partly into the corresponding opening.

6. The circuit board according to claim 1, wherein the at least one spot of relatively more solderable material comprises copper and the second circuit board layer comprises aluminum.

7. The circuit board according to claim 1, wherein the at least one opening through the first layer is defined by a rim of the relatively more solderable material.

8. The circuit board according to claim 1, wherein the at least one opening through the first layer is surrounded by a ring of an electrically conductive, relatively more solderable material than the second layer, that is soldered to the spot such that a soldered electrical connection exists between components on the first layer to the second layer by soldering to the ring.

9. The circuit board according to claim 1, further comprising at least one circuit component mounted on the first layer and electrically connected to the second layer by a soldered connection with the at least one spot.

10. The circuit board according to claim 1, wherein the relatively more solderable spot is coined into the surface of the second layer.

11. A method of assembling a circuit board comprising the steps of:
pressing into a conductive substrate at least one spot of a conductive material relatively more solderable than the substrate;
forming at least one opening through an upper circuit board layer such that the at least one opening exposes the at least one spot when the upper layer is overlaid upon the substrate; and
soldering at least one circuit component to the exposed spot.

12. The method of claim 11, further comprising the step of soldering at least one circuit component to a coined substrate.

13. The method of claim 1, further comprising the steps of:
providing a conductive rim around an edge of the at least one opening; and
soldering the at least one component to the rim.

14. The method of claim 1, wherein the step of pressing the at least one spot comprises coining the at least one spot into the substrate.

15. The method of claim 4, further comprising the step of providing a partial-shear opening in the substrate to receive the spot.
